(19) United States
(12) Patent Application Publication
(10) Pub. No.: US 2012/0306568 A1
(43) Pub. Date: Dec. 6, 2012

(54) REDUCING CROSSTALK BETWEEN MULTIPLE INTERCONNECTS

(75) Inventors: Wendemagegnehu Beyene, San Jose, CA (US); Pavle Milosevic, Portland, OR (US)

(73) Assignee: RAMBUS INC., Sunnyvale, CA (US)

(21) Appl. No.: 13/489,148

(22) Filed: Jun. 5, 2012

Related U.S. Application Data
(60) Provisional application No. 61/493,508, filed on Jun. 5, 2011.

(51) Int. Cl. H03K 17/16

(52) U.S. Cl. 327/551

(57) ABSTRACT

Embodiments reduce crosstalk between multiple interconnects in a printed circuit board environment. Further, embodiments perform frequency-dependent modal decomposition of characteristics of two or more interconnects spanning one or more integrated circuits on an interconnect substrate. In addition, each interconnect includes one or more cascaded coupled traces, where the cascaded coupled traces have one or more discontinuities in a heterogeneous medium.

### CROSS REFERENCE TO RELATED APPLICATION

This application claims priority to U.S. provisional application Ser. No. 61/493,508, entitled “REDUCING CROSSTALK BETWEEN MULTIPLE INTERCONNECTS”, filed Jun. 5, 2011 which is hereby incorporated by reference as if set forth in full in the application for all purposes.

### FIELD

The present disclosure generally relates to integrated circuit devices, and more particularly to reducing crosstalk in integrated circuit devices.

### BACKGROUND

Electronic circuits typically include electronic components such as a processor, memory, or field programmable gate array (FPGA) chips, which are coupled to one or more traces laid out on a printed circuit board. For example, an image processor component and a memory component may be coupled to traces laid out on a printed circuit board. In addition to traces, a printed circuit board also includes interconnects in some embodiments. An interconnect can be a series of cascaded coupled traces with discontinuities between electronic components, packaging, and the printed circuit board.

Crosstalk between multiple interconnects coupling electronic components in a printed circuit board environment can be generated by inherent mutual capacitances and inductances between the interconnects themselves. Crosstalk can also be generated by discontinuities along the interconnects. Crosstalk reduces the integrity of electrical signals that traverse any one of the multiple interconnects. Conventional crosstalk reduction techniques are effective for interconnects in one homogeneous medium. However, conventional interconnect technology incorporates interconnects that pass through a heterogeneous medium that can include inherent mutual capacitances and inductances between the interconnects and discontinuities along the interconnects, which are sources of crosstalk.

### BRIEF DESCRIPTION OF DRAWINGS

FIGS. 1A and 1B are functional diagrams illustrating example interconnects in a printed circuit board and package environment.

FIG. 1C is a functional diagram illustrating multiple example interconnects in a printed circuit board and package environment.

FIG. 2A is an example functional block diagram illustrating measuring the channel parameters of multiple interconnects in a printed circuit board environment using an on-chip measuring device.

FIGS. 2B-2C are function block diagrams illustrating example systems that reduce crosstalk between multiple interconnects using frequency-dependent decomposition.

FIGS. 3-4 are flow charts that show example methods for reducing crosstalk between multiple interconnects using frequency-dependent decomposition.

FIG. 5 is an example of a one-port section of the frequency-dependent termination network.

### DETAILED DESCRIPTION

The present disclosure describes devices, systems, and methods for reducing crosstalk between interconnects spanning one or more integrated circuits, between traces and discontinuities, and between traces in packages and printed circuit board environments. In some embodiments, the devices, systems, and methods perform frequency-dependent modal decomposition on characteristics or channel parameters of the interconnects. It is noted that persons of ordinary skill in the art would understand the term interconnect substrate to include the interconnects in printed circuit boards as well as the packages. In addition, each interconnect includes one or more cascaded coupled traces, the traces coupled by one or more discontinuities in a heterogeneous medium.

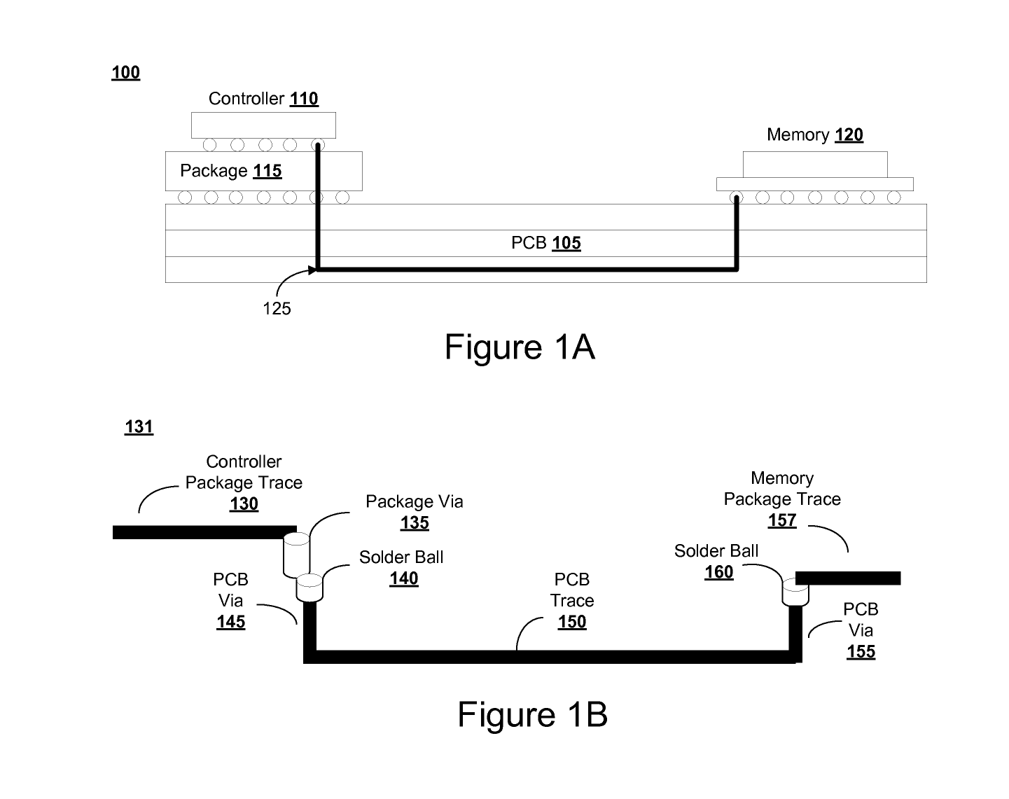

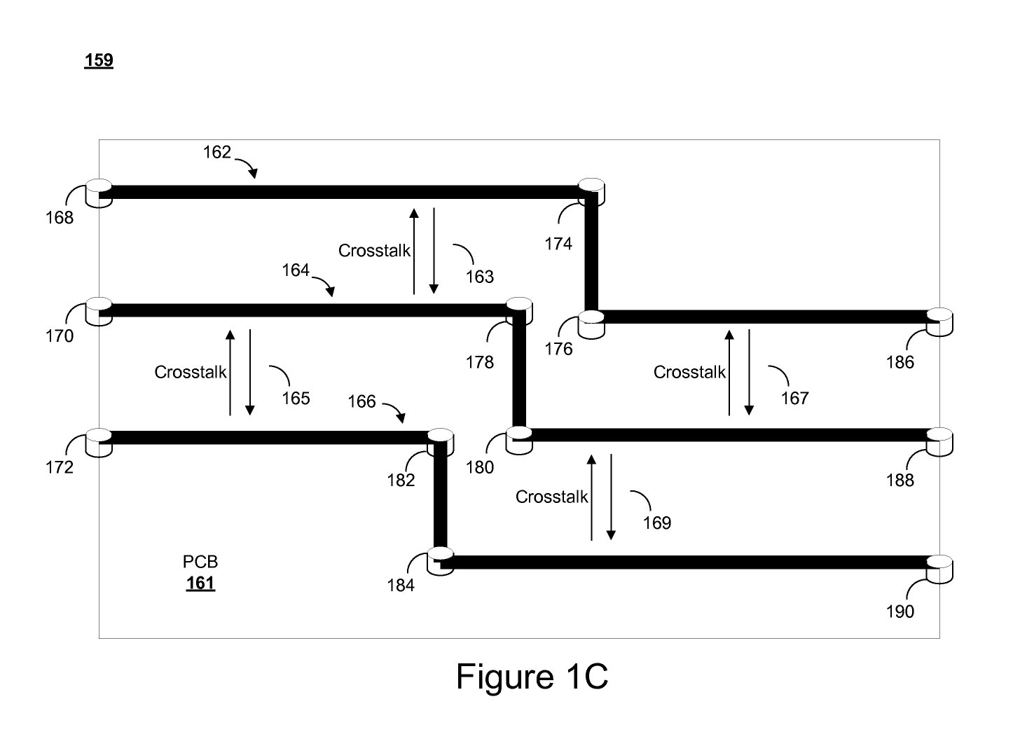

FIGS. 1A and 1B are functional diagrams illustrating example systems 100 and 131, which include interconnects in a printed circuit board environment. Referring to FIG. 1A, the system 100 includes a printed circuit board (PCB) 105 coupled to a package 115. Further, a controller 110, such as an application specific integrated circuit (ASIC), is coupled to the package 115, and both the package 115 and a memory 120 are coupled to the PCB 105. An interconnect 125 traverses the controller 110, package 115, PCB 105, and memory 120. The interconnect 125 includes cascaded coupled traces, such that one or more of the traces may have one or more discontinuities such as a via or solder ball. The cascaded traces coupled by the discontinuities may include a heterogeneous medium for traversing. Moreover, the system 100 includes an electronic circuit that enables the controller 110 to control data flow to and out of the memory 120, for example. If there are multiple interconnects traversing through the PCB 105, each interconnect carrying an electrical signal, crosstalk can be generated between the multiple interconnects. Consequently, such crosstalk may reduce the integrity of each of the electrical signals, and hence reduce the effectiveness of the controller 110 to reliably transmit or receive data, which hinders the ability of the controller 110 to control data flow to the memory 120.

Referring to FIG. 1B, the system 131 includes coupled cascaded traces of the interconnect 125 shown in FIG. 1A. The interconnect 125 includes a controller package trace 130 coupled to a package via 135. A solder ball 140 couples the package via 135 to the PCB via 145. Further, a PCB trace 150 is coupled to the PCB via 145, and is coupled to another PCB via 155. In addition, a solder ball 160 is coupled to the PCB via 155 and to a memory package trace 157. Hence, the interconnect 125 includes a heterogeneous medium of cascaded traces coupled by discontinuities such as the package via 135, solder ball 140, PCB vias 145 and 155, and solder ball 160. As discussed with reference to FIG. 1A, if there are multiple interconnects traversing through the heterogeneous medium of the PCB 105, each interconnect carrying an electrical signal, crosstalk can be generated between the multiple interconnects thereby reducing the integrity of each of the electrical signals.

FIG. 1C is an example functional diagram illustrating a system 159 that includes multiple interconnects 162, 164, and 166 in a PCB 161 environment. Each of the interconnects 162, 164, and 166 includes cascaded traces coupled by discontinuities 168-190. Each interconnect 162, 164, and 166 may carry a corresponding electrical signal. Each electrical signal can generate crosstalk 163, 165, 167, and 169 that may affect the integrity of the electrical signal carried by a neighboring interconnect. For example, the electrical signal carried by interconnect 162 may generate crosstalk that affects the electrical signal carried by interconnect 164. Alternatively, the electrical signal carried by interconnect 164 may generate crosstalk that affects, the electrical signal carried by interconnect 162.

According to some embodiments, crosstalk between electrical signals carried by multiple interconnects is reduced. According to one embodiment, modal decomposition is performed on the electrical signal carried by each interconnect, thereby reducing the crosstalk between the electrical signals. For example, a PCB environment may have two interconnects. The two interconnects include a first interconnect that carries a +5V electrical signal and a second interconnect that carries a +3V electrical signal. Modal decomposition may be performed on the two signals before traversing the two interconnects such that a Mode 1 (even mode) electrical signal carried on the first and second interconnects is +4V. Further, Mode 2 (odd mode) electrical signal carried on the first interconnect is +1V, and electrical signal carried on the second interconnect is a −1V. When the two interconnects are terminated properly, the modal electrical signals reduce the crosstalk between the two interconnects, thereby maintaining the integrity of the modal electrical signals. In one embodiment, an inverse modal decomposition function may be performed on the modal electrical signals after traversing the interconnects to generate output electrical signals.

In one embodiment, an encoder, decoder, and low-order termination network, each having corresponding parameters, perform modal decomposition on the electrical signals carried by multiple interconnects. In one embodiment, modal decomposition is performed by measuring or simulating the channel parameters of each interconnect and then processing the channel parameters in order to determine encoder, decoder, and low-order termination network parameters. In one embodiment, an interconnect is modeled as a channel carrying an electrical signal. Channel parameters may include S parameters, Y parameters, Z parameters, H parameters, ABCD parameters or any other parameters that can characterize the channel.

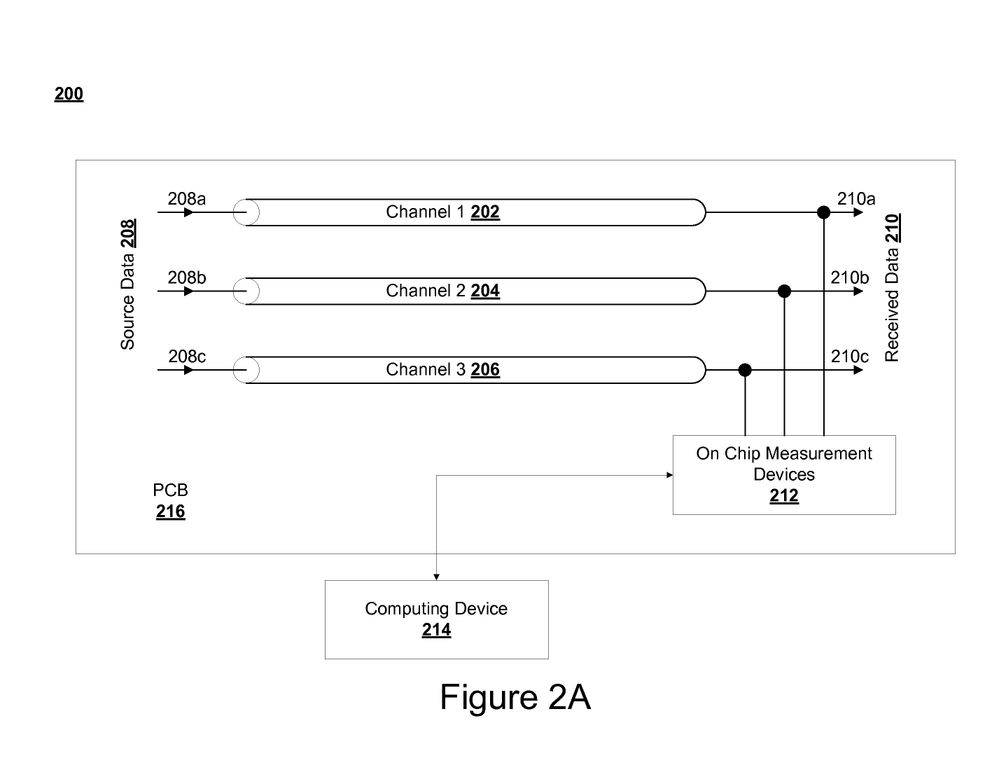

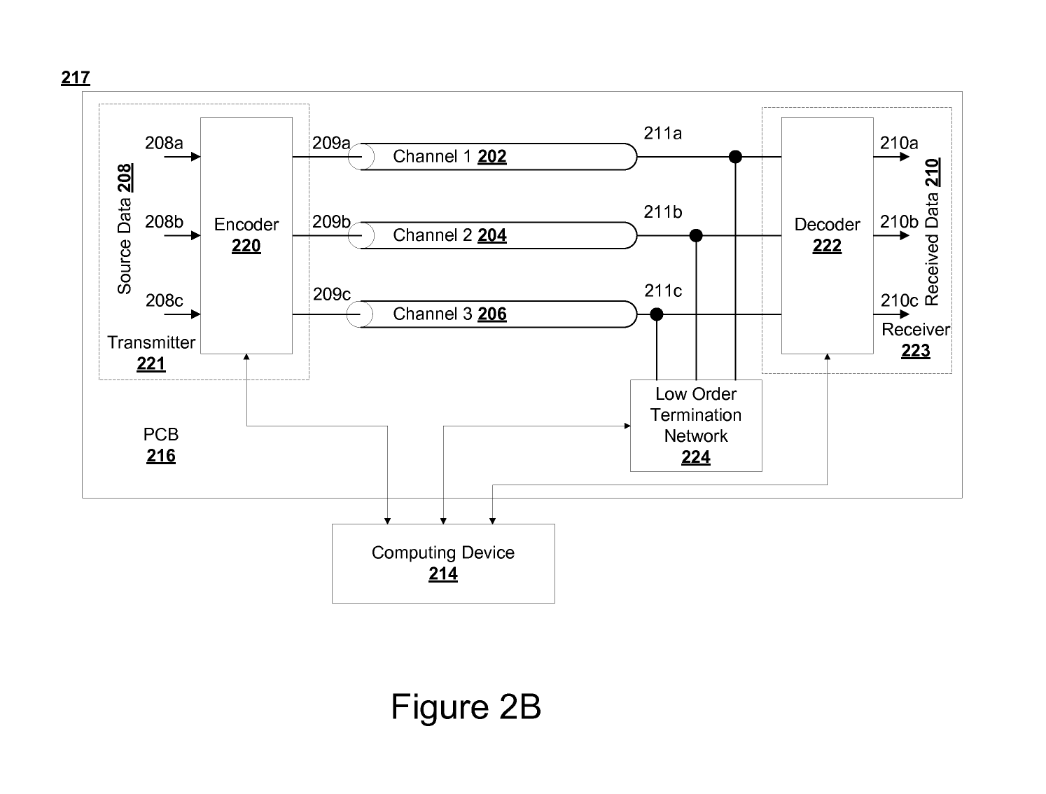

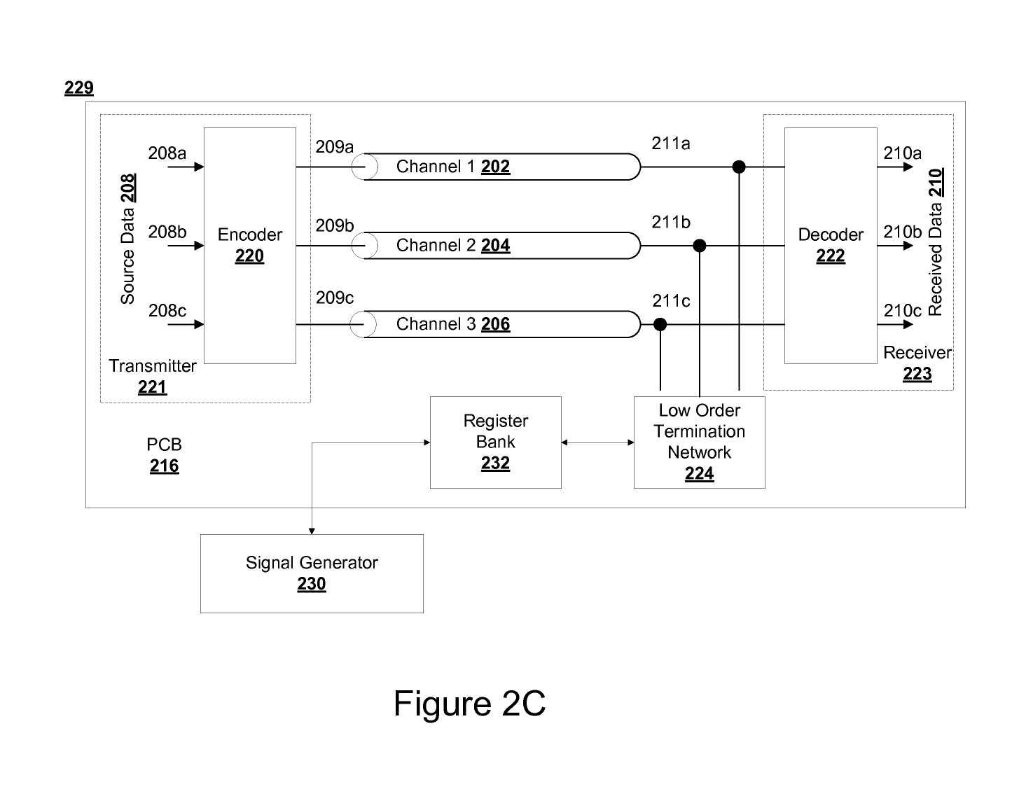

FIG. 2A is an example functional block diagram illustrating a system 200 that measures channel parameters of multiple interconnects in a PCB environment 216 using one or more on-chip measuring devices 212. Source Data 208 includes multiple input electrical signals 208a, 208b, and 208c, where each input electrical signal 208a, 208b, and 208c traverses corresponding channels 202, 204, and 206. In some embodiments, a channel is a portion of an interconnect or may be an entire interconnect. Received data 210 includes multiple output electrical signals 210a, 210b, and 210c that are collected after the input electrical signals 208a, 208b, and 208c have traversed their respective channels 202, 204, and 206. Crosstalk between the channels 202, 204, and 206 alter the electrical signals, resulting in the output electrical signals 210a, 210b, and 210c having a loss of integrity when compared to the input electrical signals 208a, 208b, and 208c. Further, one or more on-chip measurement devices 212 may be coupled to the channels 202, 204, and 206 to measure the output electrical signals 210a, 210b, and 210c. The one or more on-chip measurement devices 212 is configured to collect measurement data and to forward the measurement data to a computing device 214. In one embodiment, the on-chip measurement devices 212 measures the channel parameters of the interconnects 202, 204, and 206. In one embodiment, off-chip measurement devices may also measure the channel parameters of the interconnects 202, 204, and 206. In one embodiment, the computing device 214 analyzes the measurement data to determine the channel parameters that are in turn used to determine encoder, decoder and low-order termination network parameters.

FIG. 2B is an example functional block diagram illustrating a system 217 that reduces crosstalk between multiple interconnects. In one embodiment, the system 217 includes an encoder 220 and a decoder 222 for implementing frequency-dependent decomposition. In one embodiment, a computing device 214 processes channel parameters received by one or more on-chip measuring devices (as shown in FIG. 2A) to determine encoder, decoder and low-order termination network parameters. The computing device 214 may also configure the encoder 220, the decoder 222, and low-order termination network 224 accordingly.

Further, source data 208 includes one or more input electrical signals 208a, 208b, and 208c. In one embodiment, the encoder 220 of transmitter 221 processes each input electrical signal 208a, 208b, and 208c. In one embodiment, the encoder 220 performs modal decomposition on the input electrical signals 208a, 208b, and 208c and generates corresponding modal electrical signals 209a, 209b, and 209c to each input electrical signal 208a, 208b, and 208c. Further, each modal electrical signal traverses a corresponding channel 202, 204, and 206. The modal decomposition of the input electrical signals 208a, 208b, and 208c results in a reduction of crosstalk between the modal electrical signals carried by the multiple channels 202, 204, and 206. At the channel outputs, each modal electrical signal 211a, 211b, and 211c is then terminated by the low-order termination network 224 to provide network output electrical signals to the decoder 222. The decoder 222 processes the network output electrical signals 211a, 211b, and 211c using an inverse modal decomposition function and provides output electrical signals 210a, 210b, and 210c of the received data 210 at the receiver 223. The output electrical signals 210a, 210b, and 210c shown in FIG. 2B are less affected by crosstalk than the output electrical signals 210 shown in FIG. 2A, thereby having less integrity loss.

FIG. 2C is an example function block diagram illustrating a system 229 that reduces crosstalk between multiple interconnects using an encoder 220 and decoder 222 that implement frequency-dependent decomposition. In one embodiment, system 229 may include a signal generator 230 and a register bank 232 to implement the low-order termination network 224. The low-order termination network 224 includes one or more capacitors, one or more resistors and/or one or more inductors. In one embodiment, the printed circuit board environment 216 includes one or more dormant capacitors, one or more dormant resistors, and one or more dormant inductors. These components are configured to generate the low-order termination network based on the termination network parameters as determined by the computing device 214. The register bank 232 includes one or more registers, one or more dormant capacitors, one or more dormant resistors, and one or more dormant inductors. Further, a computing device (not shown) provides instructions to the signal generator 230 based on the termination network parameters. Subsequently, the signal generator 230 controls the register bank in order to activate a configuration of one or more dormant capacitors, one or more dormant resistors, and one or more dormant inductors to implement the low-order termination network based on the termination network parameters. Implementing the low-order termination network improves and signal integrity of the modal electrical signals 211a, 211b, and 211c by reducing reflections, thereby increasing the effectiveness of the electrical signals carried by the multiple interconnects 202, 204, and 206.

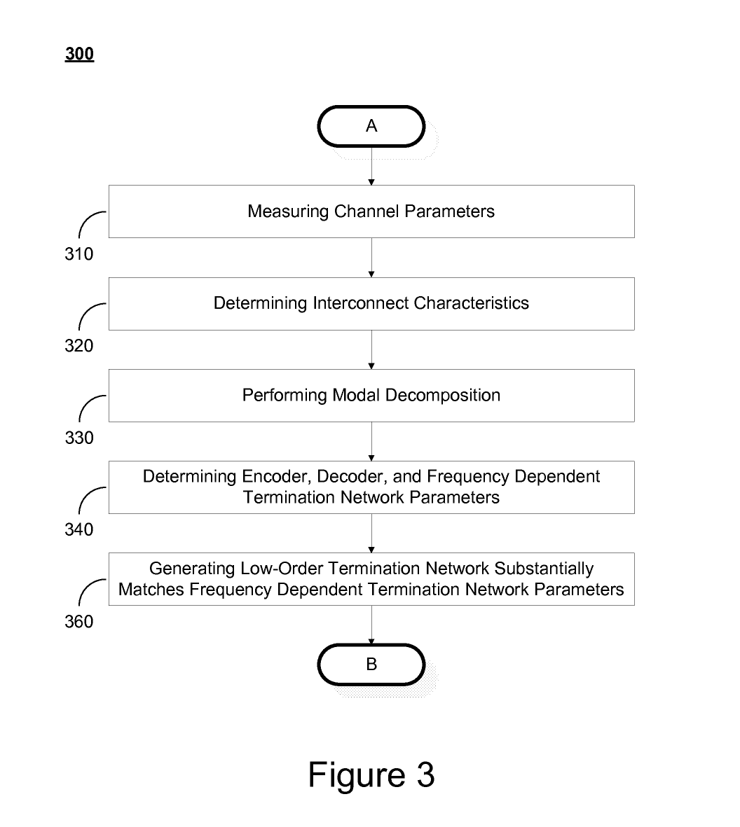

FIG. 3 is a flow chart that shows an example method for reducing crosstalk between multiple interconnects using frequency-dependent decomposition. In one embodiment, one or more on-chip measuring devices measures channel parameters, as shown in block 310. In some embodiments, the one or more on-chip measurement devices is coupled to the multiple interconnects. Off-chip measurement devices may also be used. Channel parameters may include S parameters, Y parameters, Z parameters, H parameters, ABCD parameters or any other parameters that can characterize the channel. In one embodiment, the channel parameters are to be determined by performing electromagnetic simulation using the layout design information and material properties of the interconnect substrate. In addition, the channel parameters are forwarded to a computing device.

In one embodiment, a computing device determines interconnect characteristics, as shown in block 320. In one embodiment, the computing device performs modal decomposition, as shown in block 330. In one embodiment, the computing device determines encoder, decoder, and frequency dependent termination network parameters, as shown in block 340. In one embodiment, the computing device generates a low-order termination network that substantially matches frequency dependent termination network parameters, as shown in block 350. In block 350, the computing device generates the low-order termination network by controlling a signal generator based on the termination network parameters. In one embodiment, the signal generator is coupled to a register bank that is coupled to dormant capacitors, resistors, and inductors laid out in an integrated circuit, package, or PCB. Upon receiving one or more control or activation signals from the signal generator, the register bank activates specific dormant capacitors, resistors, and inductors in order to configure a low-order termination network based on the termination network parameters. In one embodiment, the dormant capacitors, resistors, and inductors may be configured or reconfigured as different low-order termination networks depending on the termination network parameters calculated by the computing device.

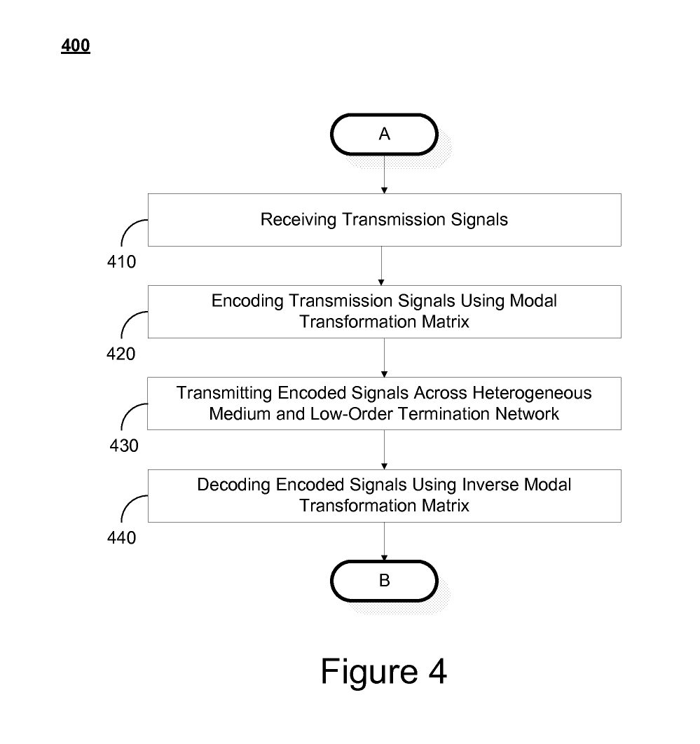

FIG. 4 is a flow chart that shows an example method for reducing crosstalk between multiple interconnects using frequency-dependent decomposition. In one embodiment, an encoder receives input electrical signals, as shown in block 410. In one embodiment, the encoder encodes the input electrical signals based on a modal transformation matrix resulting in generating modal electrical signals, as shown in block 420. In one embodiment, the encoder transmits the modal electrical signals across multiple interconnects and a low-order termination network, as shown in block 430. In one embodiment, the multiple interconnects include cascaded traces coupled by discontinuities such as vias, packaging, and solder balls, in a heterogeneous medium. The modal signals traversing the multiple interconnects reduce the crosstalk, and reduce the resulting integrity loss between the electrical signals carried by each interconnect. In one embodiment, the decoder decodes the modal electrical signals by taking the inverse of the modal transformation matrix, as shown in block 440. In one embodiment, the decoder receives the modal electrical signals after the modal electrical signals traverse the low-order termination network. After decoding the modal electrical signals, the decoder generates an output electrical signal for the electronic circuit.

### Example 1

The following is an example that implements aspects of the present disclosure. This example includes three channels or interconnects, each including two cascaded uniform segments. The first segment represents package traces, and the second segment represents PCB traces. In one embodiment, a measurement device determines the S parameters (channel parameters) and the ABCD parameters (channel parameters) of the three channels and forwards these parameters to a computing device. The computing device implements a modal decomposition computer program using the channel properties to calculate the modal decomposition function and implements an inverse of the modal decomposition function for the encoder and decoder, respectively.

The computer program generally implements modal decomposition in the following manner. In one embodiment, the channel properties for three channels in the example is expressed by following matrix equation:

[B]=[S][A] (1)

where [B] is a 3×1 matrix of reflected power wave values for each channel, [S] is a 3×3 matrix of the S parameters of the three channels as determined by the measurement device, and [A] is a 3×1 matrix of incident power wave values for each channel. Further, the computer program implementing modal decomposition yields the following matrix equation:

[B]=[E][Λ][D][A] (2)

where [B] is a 3×1 matrix of reflected power wave values for each channel, [E] is a 3×3 matrix of the encoder parameters which are found by performing modal decomposition of the [S] matrix, [Λ] is a 3×3 diagonal matrix comprising the eigenvalues of the [S] matrix, [D] is a 3×3 matrix of the decoder parameters such that [D]=[E]⁻¹, and [A] is a 3×1 matrix of incident power wave values for each channel.

In this example, the [E] is found to be the following:

$$E = [ \begin{matrix}0.423 & - 0.707 & 0.553 \\ - 0.801 & 0 & - 0.623 \\ 0.423 & 0.707 & - 0.553\end{matrix} ] \qquad ( 3 )$$

whereas [D] is found to be the following:

$$D = [ \begin{matrix}0.441 & - 0.783 & 0.441 \\ - 0.707 & 0 & 0.707 \\ - 0.567 & - 0.598 & - 0.567\end{matrix} ] \qquad ( 4 )$$

### Example 2

The following is another example that implements aspects of the present disclosure. This example includes two channels or interconnects. Further, a measurement device is used to determine the ABCD parameters (channel parameters) of the two channels, and forward the ABCD to a computing device. Further, the computing device implements a modal decomposition computer program on the channel properties to determine the termination network parameters.

In some embodiments, the computer program generally implements modal decomposition in the following manner. In one embodiment, the channel properties for two channels in the example is expressed by following matrix equation:

$$[ \begin{matrix}{v}_{S} \\ {i}_{S}\end{matrix} ] = [ \begin{matrix}A & B \\ C & D\end{matrix} ] [ \begin{matrix}{v}_{R} \\ {i}_{R}\end{matrix} ] \qquad ( 5 )$$

where A, B, C, and D are the channel network parameters and vₛ and iₛ are the voltage and current at the input port and vᵣ and iₜ are the voltage and current at the channel output.

In one embodiment, the ABCD-matrix is diagonalizable such that the computer program implementing modal decomposition yields the following:

$$[ \begin{matrix}{v}_{S} \\ {i}_{S}\end{matrix} ] = {[ \begin{matrix}{W}_{Fv} & {W}_{Bv} \\ {W}_{Fi} & {W}_{Bi}\end{matrix} ] [ \begin{matrix}{Λ}_{F} & \\ & {Λ}_{B}\end{matrix} ] [ \begin{matrix}{W}_{Fv} & {W}_{Bv} \\ {W}_{Fi} & {W}_{Bi}\end{matrix} ]}^{- 1} [ \begin{matrix}{v}_{R} \\ {i}_{R}\end{matrix} ] \qquad ( 6 )$$

where Λ_{F} and Λ_{B} are eigenvalues of the forward and backward waves and (W_{Fv}, W_{Bv}) and (W_{Fi}, W_{Bi}) submatrices are the eigenvectors of the forward- and backward-propagating voltage and current waves.

In one embodiment, the approximation of the frequency-dependent termination is performed using model-order reduction method, which calculates the poles and residues needed to rewrite, for example, the elementary one-port driving-point admittance functions as shown in the following:

$$Y ( s ) = {sY}_{∞} + {Y}_{0} + {\sum }_{m = 1}^{{N}_{R}} \frac{{a}_{m}}{s - {p}_{m}} + {\sum }_{n = 1}^{{N}_{C}} ( \frac{{a}_{n}}{s - {p}_{n}} + \frac{{a}_{n}^{*}}{s - {p}_{n}^{*}} ) \qquad ( 7 )$$

where the rational function is expanded into partial fraction form with N_{c} conjugate poles pₙ and N_{R} real poles pᵣ.

The resulting admittance submatrices describe the forward- and backward-propagating waves:

Y_{C,F}=W_{Fi}W_{Fv}⁻¹ and Y_{C,B}=W_{Bi}W_{Bv}⁻¹ (8)

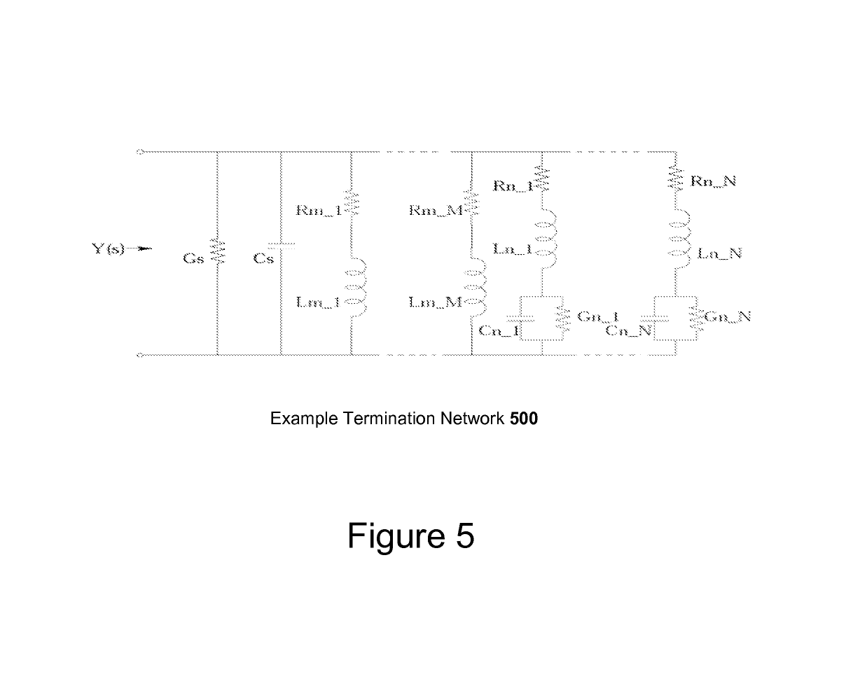

In one embodiment, for unidirectional signaling in forward direction, this example may use T=W_{Fv} or S=W_{Fi} waveshapes for signaling at a transmitter end of the two channels. Further, the channels are terminated with Yₜₑᵣₘ=Y_{C,F} to eliminate reflections and modal conversion. Retrieve the line variables by multiplying with T⁻¹ (or S⁻¹) at the receiver end of the channels. That is, decoding is performed to retrieve the original transmitted signals as propagated through the channel(s). Based on the termination network parameters, the termination network, composed of a one-port section (as shown in FIG. 5), can be configured.

In the preceding detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the figures, can be arranged, substituted, combined, separated, and designed in a wide variety of difference configurations, all of which are explicitly contemplated herein. Further, in the following description, numerous details are set forth to further describe and explain one or more embodiments. These details include system configurations, block module diagrams, flowcharts (including transaction diagrams), and accompanying written descriptions. While these details are helpful to explain one or more embodiments of the disclosure, those skilled in the art will understand that these specific details are not required in order to practice the embodiments.

Persons of ordinary skill in the art would understand that the examples described in the present disclosure are illustrative and not limiting, and that the concepts illustrated in the examples may be applied to other examples and embodiments.

Note that the functional blocks, methods, devices, and systems described in the present disclosure may be integrated or divided into different combinations of systems, devices, and functional blocks as would be known to those skilled in the art.

In general, it should be understood that the circuits described herein may be implemented in hardware using integrated circuit development technologies, or via some other methods, or the combination of hardware and software objects that could be ordered, parameterized, and connected in a software environment to implement different functions described herein. For example, the present application may be implemented using a general purpose or dedicated processor running a software application through volatile or non-volatile memory. Also, the hardware objects could communicate using electrical signals, with states of the signals representing different data.

It should be further understood that this and other arrangements described herein are for the purposes of example only. As such, those skilled in the art will appreciate that other arrangements and other elements (e.g., machines, interfaces, functions, orders, and groupings of functions, etc.) can be used instead, and some elements may be omitted altogether according to the desired results. Further, many of the elements that are described are functional entities that may be implemented as discrete or distributed components or in conjunction with other components, in any suitable combination and location.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions, or biological systems, which can, of course, vary. It is also to be understood that the terminology used herein is for the purpose of describing particular embodiments only, and is not intended to be limiting.

With respect to the use of substantially any plural terms and/or singular term herein, those having skill in the art can translate from the plural to the singular and/or from the singular to the plural as is appropriate to the context and/or application. The various singular/plural permutations may be expressly set forth herein for sake of clarity.

It will be understood by those skilled in the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”). The same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general, such a construction is intended in the sense that one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general, such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible sub-ranges and combinations of sub-ranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

We claim:

1. A method comprising:
performing frequency-dependent modal decomposition of characteristics of two or more interconnects spanning one or more integrated circuits on an interconnect substrate;
wherein each interconnect includes one or more cascaded coupled traces, the cascaded coupled traces having one or more discontinuities in a heterogeneous medium, and wherein performing the frequency-dependent modal decomposition reduces crosstalk between the two or more interconnects.

2. The method of claim 1, further comprising measuring channel parameters of the two or more interconnects using one or more on-chip measurement devices.

3. The method of claim 2, further comprising generating encoder parameters, decoder parameters, termination parameters, and frequency-dependent terminations based on frequency-dependent modal decomposition of characteristics of the two or more interconnects.

4. The method of claim 3, further comprising:
determining one or more low-order termination networks substantially matching the frequency-dependent terminations using a computing device;
providing one or more activation signals by a signal generator to one or more registers based on the determined termination parameters; and
activating one or more termination network elements using the one or more registers based on the one or more activation signals to generate the one or more low-order termination networks.

5. The method of claim 4, further comprising:
receiving two or more input electrical signals;
encoding each of the input electrical signals into a corresponding modal electrical signal based on the one or more encoder parameters;
transmitting each modal electrical signal across a corresponding interconnect, wherein the transmitted modal electrical signals are terminated using the one or more low-order termination networks; and
decoding each modal electrical signal received from the corresponding interconnect into a corresponding output electrical signal based on the one or more decoder parameters.

6. The method of claim 1, wherein the heterogeneous medium of the integrated circuit includes at least one of package traces, package vias, solder balls, printed circuit board vias, and printed circuit board traces.

7. The method of claim 3, wherein the encoder parameters include a modal transformation matrix of coefficients.

8. The method of claim 3, wherein the decoder parameters include an inverse modal transformation matrix of coefficients.

9. A system comprising:
an encoder that performs frequency-dependent modal decomposition on characteristics of two or more interconnects spanning one or more integrated circuits on an interconnect substrate;
wherein each interconnect includes one or more cascaded coupled traces, the cascaded coupled traces having one or more discontinuities in a heterogeneous medium, and wherein performing the frequency-dependent modal decomposition reduces crosstalk between the two or more interconnects.

10. The system of claim 9, further comprising one or more on-chip measurement devices coupled to the two or more interconnects on the one or more integrated circuits, wherein the one or more on-chip measurement devices determine one or more channel parameters of the two or more interconnects.

11. The system of claim 10, further comprising a computing device that receives and processes the one or more channel parameters and performs frequency-dependent modal decomposition of characteristics of the two or more interconnects to generate one or more encoder parameters, one or more decoder parameters, one or more termination parameters, and a frequency-dependent termination based on the one or more channel parameters.

12. The system of claim 11, wherein the computing device determines one or more low-order termination networks substantially matching the frequency dependent termination.

13. The system of claim 12, further comprising:
one or more registers;
a signal generator providing one or more activation signals to the one or more registers based on the one or more termination parameters; and
wherein the one or more registers activate one or more termination network elements to generate the low-order termination network based on the one or more activation signals.

14. The system of claim 12, wherein the encoder:
receives two or more input electrical signals;
encodes each of the two or more input electrical signals into two or more corresponding modal electrical signals based on the one or more encoder parameters; and
transmits each modal signal across a corresponding interconnect, wherein the transmitted modal electrical signals are terminated using one or more low-order termination networks.

15. The system of claim 14, further comprising a decoder configured to receive one or more decoder parameters from the computing device, the decoder coupled to the two or more interconnects, wherein the decoder decodes each of the one or more modal electrical signals received from a corresponding interconnect into a corresponding output electrical signal based on the one or more decoder parameters.

16. The system of claim 9, wherein the heterogeneous medium of the integrated circuit includes one or more of package traces, package vias, solder balls, printed circuit board vias, and printed circuit board traces.

17. The system of claim 11, wherein the encoder parameters include a modal transformation matrix of coefficients.

18. The system of claim 11, wherein the decoder parameters include an inverse modal transformation matrix of coefficients.

19. A device comprising:
an encoder performing frequency-dependent modal decomposition on characteristics of one or more interconnects spanning one or more integrated circuits on an interconnect substrate;
wherein each interconnect includes one or more cascaded coupled traces, the traces having one or more discontinuities in a heterogeneous medium, and wherein performing the frequency-dependent modal decomposition reduces crosstalk among the one or more interconnects.

20. The device of claim 19, further comprising one or more on-chip measurement devices coupled to the two or more interconnects on the one or more integrated circuits, wherein the one or more on-chip measurement devices determines the channel parameters of the two or more interconnects.

21. The device of claim 19, further comprising one or more registers configured to receive one or more activation signals based on one or more termination parameters and frequency-dependent terminations, wherein the one or more registers activate one or more termination network elements to generate one or more low-order termination networks based on the one or more activation signals, and wherein the one or more termination parameters and the frequency-dependent terminations are based on the characteristics of the interconnects.

22. The device of claim 19, wherein the encoder is configured to:
receive one or more encoder parameters and receive two or more input electrical signals;
encode each of the two or more input electrical signals into a corresponding modal electrical signal based on the one or more encoder parameters; and
transmit each modal signal across a corresponding interconnect and one or more low-order termination networks.

23. The device of claim 22, further comprising a decoder coupled to the two or more interconnects, wherein the decoder is configured to receive one or more decoder parameters, wherein the decoder decodes each of the one or more modal electrical signals received from corresponding interconnects into corresponding output electrical signals based on the one or more decoder parameters.

24. The device of claim 19, wherein the heterogeneous medium of the integrated circuit includes one or more of package traces, package vias, solder balls, printed circuit board vias, and printed circuit board traces.

25. The device of claim 22, wherein the encoder parameters include a modal transformation matrix of coefficients.

26. The device of claim 23, wherein the decoder parameters include an inverse modal transformation matrix of coefficients.

27. A method comprising:
receiving two or more measured waveforms each corresponding to two or more interconnects using one or more on-chip measurement devices, wherein the two or more interconnects span one or more integrated circuits on an interconnect substrate;
extracting interconnect characteristics from the one or more measured waveforms;
determining a modal transformation matrix of coefficients based on the interconnect characteristics;
determining a termination network to reduce crosstalk among the two or more interconnects; and
generating a low-order rational function to be implemented by the termination network, wherein each interconnect includes one or more cascaded coupled traces, each trace having one or more discontinuities in a heterogeneous medium.
